(19) United States
(12) Patent Application Publication
(10) Pub. No.: US 2002/0064683 A1
(43) Pub. Date: May 30, 2002

(54) Organic electroluminescence device and process for production thereof

(76) Inventors: Shinjiro Okada, Isehara-shi (JP); Akira Tsuboyama, Sagamihara-shi (JP); Takao Takiguchi, Tokyo (JP); Koji Noguchi, Sagamihara-shi (JP); Takashi Moriyama, Kawaski-shi (JP); Jun Kamatani, Kawasaki-shi (JP); Manabu Furugori, Atsugi-shi (JP)

Correspondence Address: FITZPATRICK CELLA HARPER & SCINTO, 30 ROCKEFELLER PLAZA, NEW YORK, NY, 10112, US

(21) Appl. No.: 09/995,611

(22) Filed: Nov. 29, 2001

(30) Foreign Application Priority Data
Nov. 29, 2000 (JP) 362117/2000

(51) Int. Cl. H05B 33/12; H05B 33/10

(52) U.S. Cl. 428/690; 428/917; 428/195; 428/448; 428/450; 427/66; 313/504; 313/506; 257/88

(57) ABSTRACT

An electroconductive device is constituted by an insulating substrate, a first electrode disposed on the insulating substrate, a thin layer of a chargeable material disposed in a plurality of regions on the first electrode, a layer of an electroconductive organic function material disposed on the thin layer of the chargeable material, and a second electrode disposed on the layer of the electroconductive organic function material. The electroconductive device is prepared by a process including: a step of applying a chargeable material onto a first electrode disposed on an insulating substrate to form a thin layer of said chargeable material, a step of forming a layer of an electroconductive organic function material on the layer of said chargeable material by immersing the substrate in an electrolytic solution containing ions of said electroconductive organic function material to cause adsorption of the ions of said electroconductive organic function material onto the thin layer of said chargeable material, and a step of forming a second electrode on the layer of said electroconductive organic function material.

### FIELD OF THE INVENTION AND RELATED ART

The present invention relates to an electroconductive device, particularly an organic electroluminescence (EL) device, for use in flat panel displays, projection displays, printers, etc., and a process for producing the electroconductive device.

As an organic EL device, in 1960s, a carrier injection-type organic EL device using an organic solid, such as anthracene single crystal, formed in a single layer has been extensively studied.

Thereafter, in 1980s, C. W. Tang et al has proposed a lamination-type organic EL device including a luminescence layer and a hole transport layer disposed between a hole injection electrode and an electron injection electrode (e.g., U.S. Pat. No. 4,769,292).

In these carrier injection-type EL device, a luminescence mechanism is based on a sequence of steps including: injection of electrons from a cathode and injection of holes from an anode, movement (transfer) of electrons and holes in a solid, recombination of electrons and holes, luminescence (emission of light) from formed singlet excitons.

An embodiment of the lamination-type EL device may have a layer structure including a glass substrate (anode), a film of ITO (indium tin oxide) disposed on the glass substrate, a layer of TPD (N,N′-diphenyl-N,N′-di(3-methylphenyl)-1,1′-biphenyl-4,4′-diamine) shown below disposed on the ITO film in a thickness of, e.g., ca. 50 nm, a layer of Alq3(tris(8-quinolinolato)aluminum) shown below disposed on the TPD layer in a thickness of, e.g., ca. 50 nm, and a layer of Al—Li alloy (cathode) formed by deposition on the Alq3 layer.

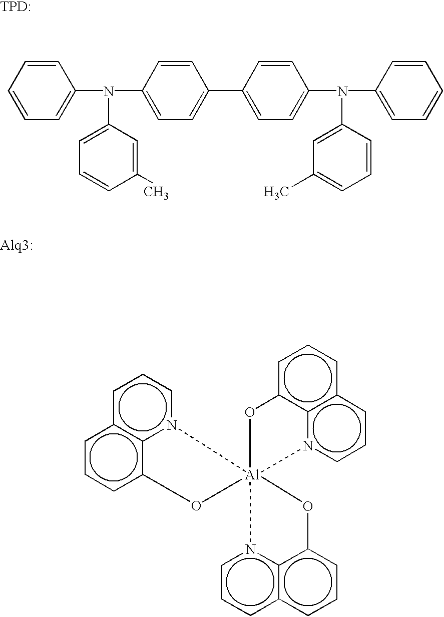

The TIO film as an anode may preferably have a work function of 4.4-5.0 eV, thus facilitating injection of holes into the TPD layer. As a cathode, it is possible to use a metal having a work function as low as possible. The metal may preferably be a chemically and electrically stable one, such as Al—Li alloy or Mg—Ag alloy.

By the use of the above-mentioned specific carrier injection-type EL device, it is possible to cause green luminescence under application of a DC of 5-10 volts.

In an ordinary organic EL device using an organic compound (e.g., TPD, α-NPD (bis-[N-(1-naphthyl)-N-phenyl]benzidine), TAZ-01 (3-4-biphenylyl)-4-phenyl-5,(4-tert-butylphenyl)-1,2,4-triazole), Alq3, etc.), it is necessary to apply a high electric field (ca. 10 volts/100 nm) at a boundary between an organic compound. layer in order to ensure a desired current amount.

Further, the organic EL device may comprise a polymeric material. It is generally known that a polymeric compound exhibiting an electroconductivity and having an unsaturated bond within its molecular structure provides good performances.

Examples of such a polymeric material may include:

(1) PPV (poly(phenylenevinylene))

(2) PPP (poly(p-phenylene))

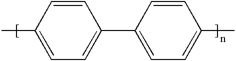

(3) PT (poly(thiophene))

(4) PVK (poly(vinylcarbazole))

(5) PDAF (poly(dialkylfluorene))

In order to prepare a color organic EL device based on combination of a plurality of colors, it is necessary to selectively form a plurality of luminescence layers comprising different luminescence materials on one substrate.

In a conventional organic EL device using a low molecular weight material, most of luminescence materials may be formed in a luminescence layer by vacuum deposition in such a manner that each of a plurality of low molecular weight materials different in species is selectively formed on a substrate by vacuum deposition with a masking member disposed on the substrate.

According to this vacuum deposition manner, however, when a pixel density is increased up to ca. 200 dpi, it becomes difficult to effect accurate positional alignment of a certain pixel (dot) located on a substrate with a masking member superposed thereon in production step, thus not readily preparing a color EL device with high definition or resolution.

On the other hand, in the case of forming a luminescence layer of a conventional polymeric material, it is difficult to employ vacuum deposition due to its properties. In this case, a precursor (monomer) of a polymeric material is applied onto a substrate by wet coating, followed by polymerization on the substrate to form a polymeric film. For this reason, it becomes more difficult to form a luminescence layer allowing a high resolution than the case of the low molecular weight material.

As described above, the preparation of a full-color EL device according to the conventional manners has its limit in terms of definition or resolution.

In order to obviate the above difficulties, Japanese Laid-Open Patent Application (JP-A) 10-12377 discloses a patterning method according to an ink jet scheme allowing selective formation of a plurality of luminescence layers for red (R), green (G) and blue (B) by attaching a plurality of liquid luminescence materials two-dimensionally onto a substrate in a desired region by means of an in jet printer.

However, when the liquid luminescence material is disposed on a flat substrate, a droplet of the material has a convex shape providing a maximum thickness at a central portion due to surface tension. As a result, a solidified luminescence material layer has a Gaussian thickness distribution such that a thickness of the material becomes zero in the vicinity of the material and a maximum at its central portion.

In order to obviate the layer thickness distribution, it is possible to use a method wherein partition walls are formed on a substrate pixel by pixel and a recess portion within each partition wall is supplied with the luminescence material.

Even when the method using partition walls is used for forming a luminescence layer, however, a resultant luminescence layer has a thickness distribution of at least 10%. The luminescence layer having such a thickness distribution causes a distribution of an applied electric field, thus involving a problem such that a threshold voltage for initiating luminescence fluctuates depending on its position.

### SUMMARY OF THE INVENTION

A principal object of the present invention is to provide an electroconductive device having solved the above-mentioned problems.

A specific object of the present invention is to provide an electroconductive device, particularly an organic EL device, wherein a plurality of different electroconductive organic function material layers are selectively formed on a (single) substrate in a uniform thickness.

Another object of the present invention is to provide a high-definition (resolution) color organic EL device including a plurality of luminescence layers different in luminescence colors with a uniform thickness in ai simple and inexpensive production process.

A further object of the present invention is to provide a process for producing the above-mentioned electroconductive device (EL device).

According to the present invention, there is provided an electroconductive device, comprising:

an insulating substrate,

a first electrode disposed on the insulating substrate,

a thin layer of a chargeable material disposed in a plurality of regions on the first electrode,

a layer of an electroconductive organic function material disposed on the thin layer of said chargeable material, and

a second electrode disposed on the layer of said electroconductive organic function material.

In the electroconductive device, the electroconductive organic function layer may preferably be divided into a plurality of organic function layers, particularly luminescence function material layers, different in species allowing emission of light (luminescence) of red (R), green (G) and blue (B). The chargeable material may preferably be an electrolyte, more preferably an electrolyte having an ion-dissociative group. Such an electrolyte may desirably have a hydrolyzable group in addition to the ion-dissociative group. In a preferred embodiment, the chargeable material has a molecular structure having a silanol group and an ion-dissociative group in combination.

According to the present invention, there is also provided a process for producing an electroconductive device, comprising at least:

a step of applying a chargeable material onto a first electrode disposed on an insulating substrate to form a thin layer of said chargeable material,

a step of forming a layer of an electroconductive organic function material on the layer of said chargeable material by immersing the substrate in an electrolytic solution containing ions of said electroconductive organic function material to cause adsorption of the ions of said electroconductive organic function material onto the thin layer of said chargeable material, and

a step of forming a second electrode on the layer of said electroconductive organic function material.

In the production process for the electroconductive device, the step of attaching the charging material may preferably be performed in accordance with an ink jet scheme by attaching a liquid chargeable material onto the first electrode in a plurality of regions. Further, the step of forming the layer of organic compound may preferably be performed by immersing the insulating substrate alternately in an electrolytic solution containing cations of an electroconductive organic function material for forming a cationic organic function layer and an electrolytic solution containing anions of an electroconductive organic function material for forming an anionic organic function layer thereby to form a plurality of cationic and anionic organic function layers, particularly as luminescence layers, alternately disposed.

The charging material and the electroconductive organic function material used in the production process of the present invention may preferably be those described above with respect to the electroconductive device of the present invention.

Herein, the term “luminescence function material” refers to not only a luminescence material used in a luminescence layer but also other functional materials used in organic layers constituting an organic EL device, such as an electron injection material, an electron transport material, a hole injection material and a hole transport material.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIGS. 1AA to 1DB are schematic plan views (FIGS. 1AA, 1BA, 1CA and 1DA) and sectional views (FIGS. 1AB, 1BB, 1CB and 1DB) for illustrating the process for producing an electroconductive device according to the present invention.

FIGS. 2A to 2C are schematic sectional views (FIGS. 2A and 2B) and a perspective view (FIG. 2C) for illustrating an embodiment of an ink jet print head used for forming a thin layer of a chargeable material constituting the electroconductive device as the present invention.

FIGS. 3AA to 3CC are schematic sectional views for illustrating a step of forming a plurality of electroconductive organic function layers involved in the production process for an electroconductive device of the present invention.

### DESCRIPTION OF THE PREFERRED EMBODIMENTS

In the present invention, a thin layer of a chargeable material is formed on an insulating substrate (provided with an electrode) at a prescribed position by locally selectively applying a liquid chargeable material onto the insulating substrate in a plurality of regions or points, and then a layer of an electroconductive organic function material, preferably a luminescence function material is formed on the thin layer of the chargeable material by immersing an electrolytic solution containing ions of the electroconductive organic function material ionized to have a sign opposite to that of the chargeable member layer surface to cause adsorption of the electroconductive organic function material onto the thin layer of the chargeable material.

More specifically, an aqueous solution of the chargeable material is selectively applied onto the insulating substrate according to an ink jet scheme to form a thin layer of the chargeable material at a desired position on the insulating substrate. The chargeable material comprises a material used for adsorption of ions of the electroconductive organic function material and may have a property of imparting chargeability to a prescribed position on the insulating substrate. Th thin layer of the chargeable material is formed by applying a very small amount (e.g., several ten pl (picoliter)) of the liquid chargeable member by means of, e.g., an ink jet printer to substantially form a monomolecular film with no thickness distribution, thus allowing formation of the layer of the electroconductive organic function material on the monomolecular film (thin layer) of the chargeable material.

Further, by using an anionic electrolyte solution containing anions of the electroconductive organic function material and a cationic electrolytic solution containing cations of the electroconductive organic function material in combination and immersing the above-treated insulating substrate into the anionic and cationic electrolyte solutions alternately, it is possible to form a plurality of organic function layers through ion adsorption, thus allowing a uniform thickness control of the resultant organic function layers.

In the present invention, after the formation of the chargeable material thin layer, the step of forming the plural organic function layers described above is repeated by changing species of electroconductive organic function materials (e.g., luminescence material for red (R), green (G) and blue (B)), thus selectively forming different electroconductive organic function layers at a desired position.

Hereinbelow, the production process for an electroconductive device according to the present invention will be described specifically with reference to the drawings.

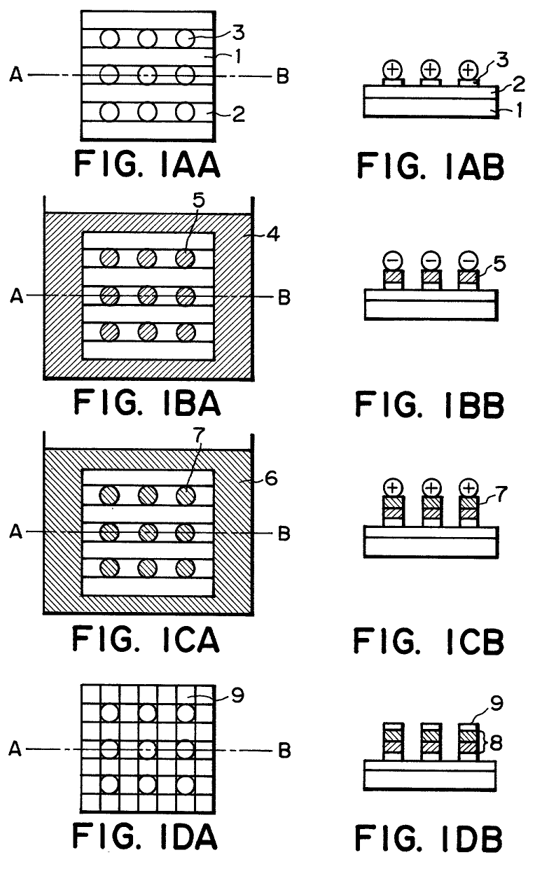

FIGS. 1AA to 1DD are schematic sectional views for explaining respective steps of the production process for the electroconductive device of the present invention, wherein FIGS. 1AA to 1DA are plan views and FIGS. 1AB to 1DB are corresponding sectional views, respectively.

Referring to these figures, the electroconductive device (organic EL device in this embodiment) according to the present invention includes an insulating substrate 1, an electrode (anode) 2, a thin layer 3 of a chargeable material, electroconductive organic function layers 5, 7 and 8, and an electrode (cathode) 9. Reference numerals 4 and 6 represent electrolyte solutions containing ions of electroconductive organic function materials.

Step (a) (FIGS. 1AA and 1AB)

On the insulating substrate 1, the electrode 2 is formed.

The insulating substrate 1 may preferably be a material which is not adversely affected at the time of layer immersion steps in the electrolytic solutions 4 and 6. In the case of constituting an organic EL device and observing luminescence from the insulating substrate side, a material for the insulating substrate may preferably be a transparent material, such as glass or plastics.

The electrode (anode) 2 may preferably comprise an electroconductive material used for an electrode structure of an ordinary device.

Examples of the electroconductive material may include ITO (indium tin oxide), indium oxide, tin oxide, Cd₂SnO₄, zinc oxide, copper iodide, gold and platinum.

In the case of preparing an organic EL device and observing luminescence from the insulating substrate side, it is preferred to use a transparent electroconductive material such as ITO as the electrode 2.

On the electrode 2, a thin layer 3 of the chargeable material is formed in a plurality of prescribed regions on the insulating substrate 1 (FIGS. 1AA and 1AB). More specifically, in the present invention, a liquid chargeable material may preferably be selectively applied at selected points onto the electrode 2 according to the ink jet scheme and dried to form a thin layer 3 of the chargeable material (positively charged in this embodiment as shown in FIG. 1AB).

The chargeable material may be any material exhibiting positive or negative chargeability in the electrolytic solution 4. In the case of forming the chargeable material thin layer according to the ink jet scheme, the chargeable member is applied in a dot pattern onto the electrode 2 disposed on the insulating substrate 1 in a liquid form, thus being required to be dissolved or dispersed in the liquid (e.g., an aqueous solution). For this reason, the chargeable material may preferably be one having an ion-dissociative group, such as an electrolyte.

Further, the chargeable material is required to b firmly attached to the electrode 2 so as not to be dissolved in the electrolyte solution 4 in the subsequent immersion step therein.

Accordingly, it is preferred to use as the chargeable member an electrolyte having an ion-dissociative group and a hydrolyzable group for ensuring adhesive function to the electrode 2.

More specifically, the chargeable member may preferably have a silanol group and an ionic group (cationic or anionic group) in combination in the electrolytic solution 2 and may desirably have a carbon number of 1-10, preferably 1-5. Further, a molecular length of the chargeable material affects a degree of supply of carriers (holes and electrons) from the electrode 2 to the electroconductive organic function layers. Accordingly, the chargeable material may desirably have a molecular length of 0.15-2 nm, particularly 0.15-1 nm, so as to allow tunnel current flow.

Examples of the above-mentioned chargeable material having a silanol group and an ionic group may include those represented by the following formulas (I-a) and (I-b):

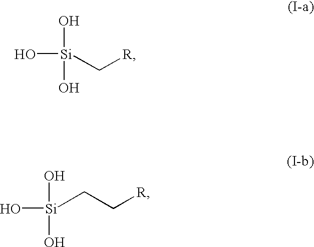

wherein R represents an ionic group shown below together with a counter ion.

<Positively Charged Group>

—NH₃+Br—

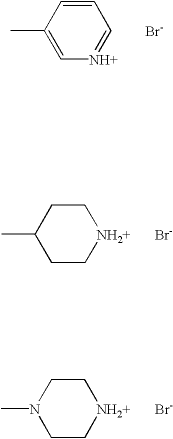

<Negatively Charged Group> 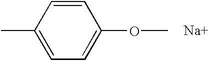 —COO—Na+ 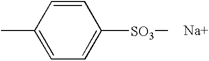 —SO₃—Na+

In the case where the chargeable material is attached onto the electrode 2 in accordance with the ink jet scheme, it is preferred to use an aqueous solution containing the chargeable material in an amount of 0.01-10 wt. %, more preferably 0.1-5 wt. %. It is also possible to appropriately add a lower alcohol such as methanol into the aqueous solution in order to control a drying speed of the attached chargeable material. The drying of the aqueous solution may be performed under heating as desired.

Step (b) (FIGS. 1BA and 1BB)

The insulating substrate 1 provided with the electrode 2 and the above-formed chargeable material thin layer 3 is immersed or dipped in the electrolytic solution 4 containing an electroconductive organic function material as shown in FIG. 1BA.

The electroconductive organic function material used in the present invention comprises an electrolyte having an ion-dissociative group and is (ion-)dissociated into ions (anions or cations). The sign of the ions of the electroconductive organic function material ((−) in this embodiment) is opposite to that (+) of the chargeable material, so that the anions of the electroconductive organic function material are adsorbed by the surface of the chargeable material thin layer 3 in the electrolytic solution 4 to form a layer 5 of the electroconductive organic function material as shown in FIG. 1BB.

The electroconductive organic function material as the electrolyte may be a low-molecular weight material or a polymeric material, preferably a polymeric material having an ion-dissociative group.

In the case where the electroconductive organic function material is used as a luminescence material for forming a luminescence layer constituting an organic EL device, examples of the luminescence material may preferably include polymeric materials having an ion-dissociative group as a side chain, such as PPV, PPP, PT, PVK, PDAF having a molecular structure into which an ion-dissociative group is introduced as a side chain.

Specific examples of the polymeric material (electroconductive organic function material) may include PPV derivatives shown below, PPP derivatives shown below (and also described in Rubber et al. “Adv. Mater.”, 10, No. 17, pp. 1452-1455 (1998)), and PT derivatives shown below.

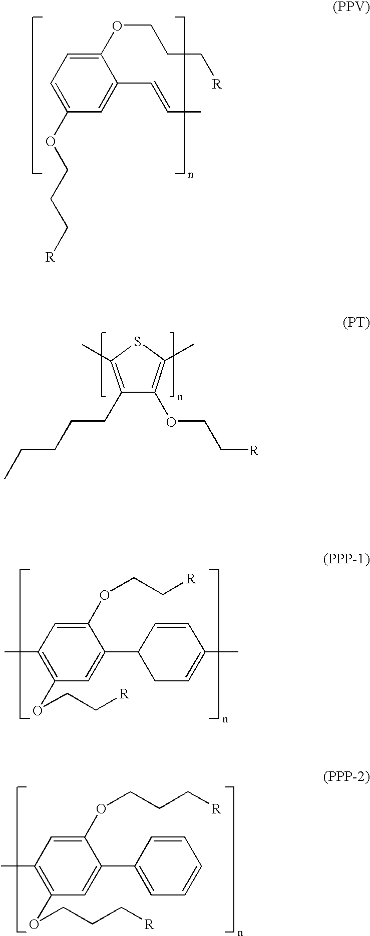

In the above structural formulas, R represents an ionic group shown below together with a counter ion.

<Positively Charged Group>

—NH₃+Br—

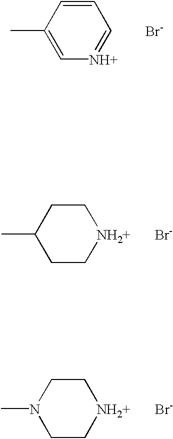

<Negatively Charged Group> 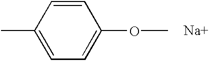 —COO—Na+ 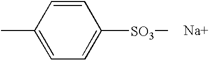 —SO₃—Na+

Step (c) (FIGS. 1CA and 1CB)

The insulating substrate 1 having thereon the electroconductive organic function layer 5 is then immersed into a cationic electrolytic solution 6 containing cations of an electroconductive organic function material as shown in FIG. 1C.

The positively charged electroconductive organic function material is adsorbed by the negatively charged surface of the electroconductive organic function layer 5 in the cationic electrolytic solution 6 to form a fresh electroconductive organic function layer 7 as shown in FIG. 1CB.

By repeating the above-described steps (b) and (c) alternately, it is possible to prepare a lamination layer 8 of electroconductive organic function materials including the anionic electroconductive organic function layer 5 and the cationic electroconductive organic function layer 7 superposed on each other layer by layer.

As a result, it becomes possible to uniformly control the thickness of the resultant electroconductive organic function (lamination) layer 8 by appropriately setting the number of repeating steps (b) and (c).

The anionic and cationic electroconductive organic function materials may preferably have an identical molecular structure except for the ionic side chains (different in sign of ions) but may have molecular structures different from each other in their main chains.

Step (d) (FIGS. 1DA and 1DB)

On the electroconductive organic function (lamination) layer 8, an electrode 9 is formed as a cathode to prepare an electroconductive device of the present invention as shown in FIGS. 1DA and 1DB.

A material for the electrode (cathode) 9 may comprise alkaline metals, alkaline earth metals and alloys thereof, examples of which may include: sodium, potassium, magnesium, lithium, sodium-potassium alloy, magnesium-indium alloy, magnesium-silver alloy, aluminum, aluminum-lithium alloy, aluminum-copper alloy, and aluminum-copper-silicon alloy.

The electrodes (anode and cathode) 2 and 9 may be disposed oppositely to sandwich the lamination layer 8 (electroconductive organic function layers) and are supplied with a voltage in the above-described embodiment.

However, the positions and shapes of the electrodes 2 and 9 used in the present invention may appropriately be changed depending on species of an electroconductive device used as long as a voltage is applied between the electrodes 2 and 9. For example, the positions of the electrodes 2 and 9 may be replaced with each other.

In the case of preparing a simple matrix drive-type organic EL device, the electrodes 2 and 9 may be respectively arranged in an stripe shape so as to form a matrix of pixels each at an intersection of these stripe electrodes. At each pixel, the lamination layer (luminescence layer) 8 may be formed.

In the case of preparing the active matrix drive-type organic EL device, the electrode 2 is arranged to form pixel electrodes each provided to a switching element (e.g., TFT (thin film transistor)) and the electrode 9 is arranged to form a common electrode disposed opposite to the pixel electrodes. Between these electrodes 2 and 9, the lamination layer 8 is disposed.

In the case where a color organic EL device using a plurality of electroconductive organic function layers different in molecular structure, e.g., for forming different luminescence layers for red (R), green (G) and blue (B), the steps (a), (b) and (c) are employed as one cycle for forming one lamination layer 8 and repeated appropriately depending on the number of the plurality of different lamination layers 8. As a result, it is possible to selectively form different lamination layers 8 at a desired position.

In this embodiment, an outermost (surface) layer constituting the lamination layer 8 may preferably be subjected to neutralizing treatment, such as oxidation treatment for cations or reduction treatment for anions, thus suppressing ion adsorption of a fresh electroconductive organic function layer on the outermost layer in subsequence steps.

When the EL device is prepared, it is possible to form an electroconductive organic function layer of an electron (or hole) transport material and/or an electroconductive organic function layer of an electron (or hole) injection layer for all the electroconductive organic function (luminescence) layers 8 (5 and 7) by vacuum deposition.

Examples of a hole transport material usable in the present invention may include those shown below.

[chemical structure]

1-TANTA: 4,4′,4″-tris(1-naphthylphenylamino)-triphenylamine

2-TANTA: 4,4′,4″-tris(2-naphthylphenylamino)-triphenylamine

TCTA: 4,4′-4″-tris(N-carbazoyl)triphenylamine

p-DPA-TDAB: 1,3,5-tris[N-(4-diphenylamino-phenylamino]benzene

TDAB: 1,3,5-tris(diphenylamino)benzene

TDTA: 4,4′,4″-tris(diphenylamino)triphenylamine

TDAPB: 1,3,5-tris[(diphenylamino)phenyl]benzene

Further, examples of an electron transport material usable in the present invention may include those shown below in addition to the above-described Alq3.

BeBq: bis(benzoquinolinolato)beryllium complex

DTVBi: 4,4′-bis-(2,2-di-p-tolyl-vinyl)-biphenyl

Eu(DBM)3(phen): tris(1,3-diphenyl-1,3-propane-diono(monophenanthroline)Eu (III)

Other hole and electron transport materials usable in the present invention may include: diphenylethylene derivatives, triphenylamine derivatives, diaminocarbazole derivatives, bisstyryl derivatives, benzothiazole derivatives, benzoxazole derivatives, aromatic diamine derivatives, quinacridon-based compounds, perylene-based compounds, oxadiazole derivatives, coumarin-based compounds, anthraquinone derivatives, distylarylene derivatives (DPVBi), and oligothiophene derivatives (BMA-3T).

These materials may preferably be formed in a layer in an amorphous state by vacuum deposition.

The ink jet scheme employed for forming a thin layer of the chargeable material adopted in the present invention may preferably be performed by using an ink jet printer including an ink jet print head.

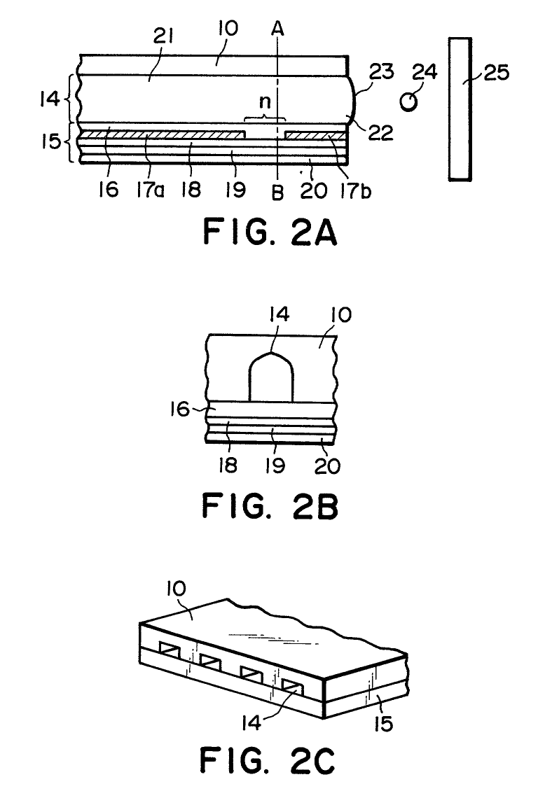

FIGS. 2A to 2C shows an embodiment of the ink jet print head for the ink jet printer. Specifically, FIG. 2A is a schematic sectional view of the ink jet head along an ink jet direction and FIG. 2B is a schematic sectional view of the ink jet print head along A-B lien shown in FIG. 2A. FIG. 2C is a schematic perspective view of the ink jet print head.

The ink jet print head shown in these figures is of a bubble jet-type using an electrothermal (electricity-heat) conversion device as an energy-generating device. In the present invention, it is possible to use an ink jet print head of a piezo-jet type using a piezoelectric device.

Referring to FIGS. 2A to 2C, the ink jet head include a support 10, grooves 14 as an ink flow passage, a thermal head 15, a protective film 16, aluminum electrodes 1a and 17b, a heat resistor layer 18, heat-storage layer 19, a substrate 20, an ink 21, an orifice 22, and a meniscus 23. A droplet 24 of the ink 21 is emerged from the orifice 22 toward an electrode 25 as shown in FIG. 2A.

The ink jet print head may generally be prepared by bonding together the support 10 comprising glass, ceramics, plastics, etc., provided with the grooves 14 through which the ink 21 is passed, and the thermal head 15 ordinarily used for thermal recording.

The thermal head 15 includes the protective layer 16 of, e.g., silicon oxide, the aluminum electrodes 17a and 17b, the heat resistor layer 18 of, e.g., nichrome, the heat-storage layer 19, and the substrate 20 of, e.g., alumina having a good heat dissipation performance.

The ink 21 carried to the orifice (minute opening) 22 forms the meniscus 23. When an electric signal is supplied to the electrodes 17a and 17b, a region n of the thermal head 15 is abruptly heated to generate a bubble within a portion of the ink 21 in contact with the region n. Under a pressure of the bubble generation, the meniscus 23 is protruded to emerge the droplet 24 of the ink 21 from the orifice 22 and be jetted toward the electrode 25 as an ink-receiving member.

The ink jet print head may generally be formed as a multiple head including a plurality of the head structures described above as shown in FIG. 2C.

The electroconductive device of the present invention may preferably be used as the organic EL device as described above. In addition thereto, the electroconductive device of the present invention may be applicable to various electronic devices, such as an optical sensor, a photoconductive member (e.g., a photosensitive member for a copying machine), an organic semiconductor device (e.g., an organic TFT device), a temperature sensor and a space modulation device.

Hereinbelow, the present invention will be described more specifically based on Examples.

### EXAMPLE 1

An organic EL device (as an electroconductive device) was prepared in the following manner.

On a 1.1 mm-thick glass substrate, a 70 nm-thick ITO (indium tin oxide) film (transparent electrode as an anode) was formed by sputtering under the following conditions, followed by patterning in an ordinary manner.

Substrate temperature: 200° C.

Target: In/Sn=90/10

Gas flow rate: Ar (200 sccm)/O₂ (3 sccm)

The thus-formed ITO film showed a work function of ca. 4.35 eV.

Thereafter, the ITO film formed on the glass substrate was subjected to ultraviolet (UV) light irradiation by means of a low-pressure mercury lamp thereby to increase the work function up to 4.6 eV.

An aqueous solution containing 0.1 wt. % of a positively chargeable material 1 shown below and 5 wt. % of methanol was prepared.

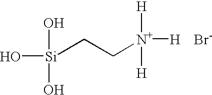

The aqueous solution was applied in an amount of 30 pl/dot (pixel) onto the ITO film surface by using an ink jet printer, followed by heating at 80° C. to remove a part of the chargeable material 1 which was not reacted with the substrate. Thereafter, at that temperature, the thus-treated substrate was subjected to drying under a reduced pressure of 2×10⁻² Pa in a vacuum system, thus forming a thin layer of the positively chargeable material 1 having a diameter of ca. 0.15 nm.

A 0.01 M-cationic electrolytic solution (pH=ca. 4) containing a PPP derivative 1 shown below (n=10) and a 0.01 M-anionic electrolytic solution (pH=ca. 4 adjusted by addition of NaCl aqueous solution) containing PPP derivative 2 (n=10) shown below were prepared in accordance with processes described in “Langmuir”, 16, No. 11, pp. 5017-5023 (2000) and “Adv Mater.”, 10, No. 17, page 1452 (1998).

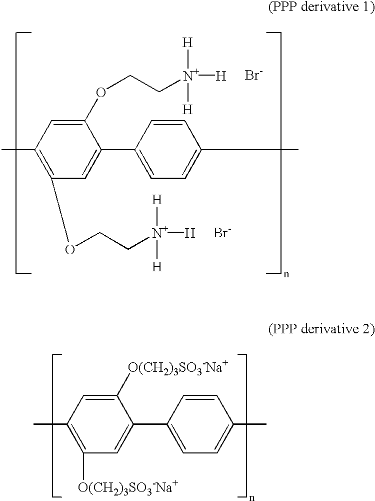

The above-treated glass substrate (provided with the ITO film and the thin layer of the positively chargeable material 1) was immersed in the anionic electrolytic solution containing anions of the PPP derivative 2 for 15 min., followed by rinsing in water for 2 min. and then drying. Thereafter, the thus-treated glass substrate was immersed in the cationic electrolytic solution containing cations of the PPP derivative 1 for 15 min., followed by rinsing in water for 2 min. and then drying.

This immersion operation as one cycle was repeated 20 times to form a ca. 100 nm-thick luminescence layer (lamination layer). The substrate was then dipped in a 1%-acetic acid solution for 5 min., followed by drying in a vacuum oven (neutralization treatment). At that time, the resultant luminescence layer had substantially no thickness unevenness when the thickness of the layer was measured by a sensing pin-type thicknessmeter.

The thus-treated glass substrate was then placed in a vacuum chamber, followed by resistance-heating vacuum deposition with Alq3 under a reduced pressure of 1×10⁻³ Pa at a deposition rate of ca. 0.1 nm/sec to form a ca. 30 nm-thick Alq3 layer (electron transport layer).

On the Alq3 layer, a ca. 10 nm-thick Al—Li alloy layer and a 150 nm-thick Al layer as an electrode (cathode) were successively formed by vacuum deposition under a reduced pressure of 1×10⁻⁴ Pa to prepare an organic EL device.

The thus-prepared organic EL device was supplied with a voltage of 12 volts between the anode (ITO film) and the cathode (Al—Li alloy electrode), whereby luminescence was caused to occur.

Within a luminescence region of the EL device, there was substantially no threshold value distribution with respect to a luminescence initiation voltage. Accordingly, the EL device was found to exhibit a uniform luminescence threshold characteristic.

### EXAMPLE 2

A simple matrix-type organic EL device was prepared in the following manner.

On a 1.1 mm-thick glass substrate, a ca. 100 nm-thick ITO film (anode) was formed by sputtering, followed by patterning into a stripe electrode including 10 lines each having a width of 100 μm and a spacing of 40 μm.

Then, a positively chargeable material 1 was applied in an amount of 20 pl/dot (pixel) onto the ITO film surface at prescribed selected points (corresponding to intersections (dots) of the ITO stripe electrode with a stripe electrode of a cathode to be formed later) in the same manner as in Example 1 according to the ink jet scheme, thus forming a circular thin layer (diameter: ca. 0.1 mm) of the chargeable material 1.

On the thin layer, in the same manner as in Example 1, a ca. 100 nm-thick luminescence layer (lamination layer) was formed. Substantially no thickness unevenness of the luminescence layer was observed similarly as in Example 1.

As a cathode, a lamination metal electrode including a 10 nm-thick Al—Li (Li=1.3 wt. %) alloy layer and a 150 nm-thick Al layer (disposed on the Al—Li alloy layer) was formed on the luminescence layer by vacuum deposition under reduced pressure of 2.66×10⁻³ Pa, followed by patterning into a stripe electrode including 10 lines each having a width of 100 μm and a spacing of 40 μm so that the lines of the metal electrode (cathode) and the ITO film (anode) intersected with each other at right angles to form a matrix of dots (pixels), thus preparing an organic EL device of a simple matrix-type.

The thus-prepared organic EL device was placed in a glove box in a nitrogen atmosphere and driven by supplying thereto a drive signal of 7-13 volts including a scanning line signal (pulse voltage) of +10 volts and a data line signal (alternating voltage applied to the metal electrode 9) of ±3 volts in a line sequential manner at a frame frequency of 30 Hz.

As a result, it was confirmed that the EL device provided smooth motion picture images.

Further, when the EL device was continuously driven in the above driving manner, the EL device provided a luminescence half-life of 60 hours as a time required for decreasing an initial luminance to ½ thereof.

### EXAMPLE 3

A sample matrix-type organic color EL device provided with a multi-color luminescence portion was prepared in the following manner.

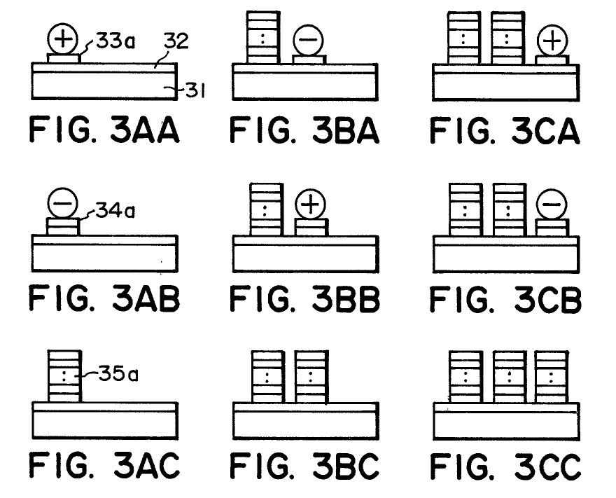

FIGS. 3AA to 3CC are schematic sectional views for illustrating color luminescence layer forming steps including a first luminescence layer forming step (FIGS. 3AA to 3AC), a second luminescence layer forming step (FIGS. 3BA to 3BC) and a third luminescence layer forming step (FIGS. 3CA to 3CC).

Referring to these figures, the color EL device includes a glass substrate 31, an anode 32, chargeable materials 33a to 33c, electroconductive organic function layers 34a to 34c, and a lamination luminescence layers 35a to 35c.

On a 1.1 mm-thick glass substrate 31, a 70 nm-thick ITO film (stripe electrode as an anode) 32 was formed by sputtering in the same manner as in Example 1, followed by patterning into a stripe electrode including 10 lines each having a width of 100 μm and a spacing of 40 μm.

Onto the ITO film surface, an aqueous solution containing 0.1 wt. % of a positively chargeable material and 5 wt. % of methanol was applied in an amount of 20 pl/dot by using an ink jet printer at prescribed selected points (corresponding to intersections (for pixels for dots for blue) of the ITO stripe electrode with a stripe electrode (including 10 lines) of a cathode to be formed later, located on 1st, 4th, 7th and 10th cathode stripe lines), followed by vacuum drying to form a thin layer 33a of the positively chargeable material 1 as shown in FIG. 3AA.

The above-treated glass substrate 31 (provided with the ITO film 32 and the thin layer 33a of the positively chargeable material 1 selectively locally arranged on the ITO film 32) was then immersed in an anionic electrolytic solution containing anions of a PPP derivative 2 (n=10) for 15 min., followed by rinsing in water for 2 min. and then drying, thus forming an anionic electroconductive organic function layer 34a. Thereafter, the thus-treated glass substrate 31 was immersed in a cationic electrolytic solution containing cations of a PPP derivative 1 (n=10) for 15 min., followed by rinsing in water for 2 min. and then drying to form a cationic electroconductive organic function layer as shown in FIG. 3AB.

This immersion operation as one cycle was repeated 20 times to form a ca. 100 nm-thick first luminescence layer (lamination layer) 35a for blue (B) luminescence, followed by electrically neutralizing treatment (oxidation treatment in this case) of the outermost cationic electroconductive organic function layer by adding dropwise a 1%-acetic acid aqueous solution thereto in an amount of ca. 20 pl by the ink-jet scheme (FIG. 3AC), thus obviating adsorption thereto of another luminescence material for different color in subsequent step.

In the same manner as in the above step of the thin layer formation shown in FIG. 3AA, a thin layer 33b of a negatively chargeable material 2 shown below was formed at prescribed points shifted (for a longer-wavelength color) from the dots of the thin layer 33a by 140 μm, respectively, located on 2nd, 5th and 8th cathode stripe lines, by changing the positively chargeable material 1 to the negatively chargeable material 2 (FIG. 3BA).

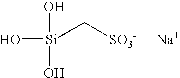

Then, in the same manner as in the above steps of the first luminescence layer formation shown in FIGS. 3AB and 3AC, a ca. 100 nm-thick second luminescence layer 35b including a cationic electroconductive organic function layer 34b was formed by using PPP derivatives 1 (n=30) and 2 (n=30) in this order (opposite to the order for the first luminescence layer 35a) for shifting a luminescence wavelength toward the red side, followed by neutralization treatment with a 1%-eethanol amine (β-aminoethyl alcohol) aqueous solution added dropwise (ca. 20 pl) by the ink-jet scheme (FIGS. 3BB and 3BC).

Then, in the same manner as in the above step of the thin layer formation shown in FIG. 3BA, a thin layer 33c of a positively chargeable material 1 was formed at prescribed points (for a shorter-wavelength color) shifted from the dots of the thin layer 33b by 140 μm, respectively, located on 3rd, 6th and 9th cathode stripe lines, by changing the negatively chargeable material 2 to the positively chargeable material 1 (FIG. 3CA).

Thereafter, in the same manner as in the above steps of the second luminescence layer formation shown in FIGS. 3BB and 3BC, a ca. 100 nm-thick second luminescence layer 35c including a cationic electroconductive organic function layer 34c was formed by using PPP derivatives 2 (n=5) and 1 (n=5) in this order (opposite to the order for the second luminescence layer 35b) for shifting a luminescence wavelength toward the blue side, followed by neutralization treatment with a 1%-acetic acid aqueous solution in the same manner as in the case of the first luminescence layer 35a. (FIGS. 3CB and 3CC).

The thus-treated glass substrate was then placed in a vacuum chamber, followed by resistance-heating vacuum deposition under a reduced pressure of 2×10⁻³ Pa to form a ca. 150 nm-thick (in total) lamination metal electrode including an Al—Li (Li=1.3 wt. %) alloy layer and an Al layer (disposed on the Al—Li alloy layer) formed as a cathode on the first to third luminescence layers 35a, 35b and 35c, followed by patterning with a mask into a stripe electrode including 10 lines (1st to 10th lines) each having a width of 100 μm and a spacing of 40 μm so that the lines of the metal electrode (cathode) and the ITO film (anode) intersected with each other at right angles to form a matrix of dots (pixels) for luminescence of different colors, thus preparing an organic color EL device of a simple matrix-type.

When the thus-prepared organic color EL device was driven in the same manner as in Example 2, uniform color luminescences from the first to third luminescence layers 35a, 35b and 35c were confirmed, respectively, free from irregularity in luminance for each color dot and also over the same color dots.

As described hereinabove, according to the present invention, it is possible to selectively from electroconductive organic function layers at desired positions with a uniform thickness.

Further, by changing species of the electroconductive organic function materials, it becomes possible to readily form different electroconductive organic function layers (e.g., three luminescence layers different in color) on the same substrate while strictly controlling the thicknesses of the different electroconductive organic function layers.

As a result, various devices can be prepared by using the electroconductive device of the present invention. Particularly, it becomes possible to inexpensively provide an organic color EL device with a uniform threshold voltage over a luminescence region by employing a simple production process with a good production yield.

What is claimed is:

1. An electroconductive device, comprising:
an insulating substrate,
a first electrode disposed on the insulating substrate,
a thin layer of a chargeable material disposed in a plurality of regions on the first electrode,
a layer of an electroconductive organic function material disposed on the thin layer of said chargeable material, and
a second electrode disposed on the layer of said electroconductive organic function material.

2. A device according to claim 1, wherein the layer of said electroconductive organic function material is divided into a plurality of function layers of organic function materials different in species.

3. A device according to claim 1, wherein said charging material comprises an electrolyte.

4. A device according to claim 3, wherein said electrolyte has a silane group and an ion-dissociative group.

5. A device according to claim 1, wherein said electroconductive organic function material comprises a luminescence function material.

6. A device according to claim 1, wherein a voltage is applied between the first and second electrodes to cause luminescence from the layer of said electroconductive organic function material.

7. A process for producing an electroconductive device, comprising at least:
a step of applying a chargeable material onto a first electrode disposed on an insulating substrate to form a thin layer of said chargeable material,
a step of forming a layer of an electroconductive organic function material on the layer of said chargeable material by immersing the substrate in an electrolytic solution containing ions of said electroconductive organic function material to cause adsorption of the ions of said electroconductive organic function material onto the thin layer of said chargeable material, and
a step of forming a second electrode on the layer of said electroconductive organic function material.

8. A process according to claim 7, wherein the step of attaching the charging material is performed in an ink jet scheme.

9. A process according to claim 7, wherein the step of forming the layer of organic compound is performed by immersing the insulating substrate alternately in an electrolytic solution containing cations of an electroconductive organic function material for forming a cationic organic function layer and an electrolytic solution containing anions of an electroconductive organic function material for forming an anionic organic function layer thereby to form a plurality of cationic and anionic organic function layers alternately disposed.

10. A process according to claim 7, wherein said charging material comprises an electrolyte.

11. A process according to claim 10, wherein said electrolyte has a silane group and an ion-dissociative group.

12. A process according to claim 7, wherein said electroconductive organic function material comprises a luminescence function material.
